(19) United States
(12) Patent Application Publication
(10) Pub. No.: US 2019/0326534 A1
(43) Pub. Date: Oct. 24, 2019

(54) QUANTUM DOT FILM AND APPLICATIONS THEREOF

(71) Applicant: SABIC GLOBAL TECHNOLOGIES B.V., Bergen op Zoom (NL)

(72) Inventors: Kahee SHIN, Seoul (KR); Sun Young LEE, Seoul (KR); Jeongmin LIM, Gyeonggi-do (KR); Chunim LEE, Gyeonggi-do (KR); Jong Woo LEE, Seoul (KR); Soonyoung HYUN, Gyeonggi-do (KR)

(21) Appl. No.: 16/467,540

(22) PCT Filed: Dec. 7, 2017
(86) PCT No.: PCT/IB2017/057736

§ 371 Date: Jun. 7, 2019

Related U.S. Application Data
(60) Provisional application No. 62/431,079, filed on Dec. 7, 2016.

(51) Int. Cl. H01L 51/50; H01L 33/06; H01L 33/26; H01L 33/56; H01L 31/0352; H01L 33/50; H05B 33/20; C09K 11/88; C09K 11/02

(52) U.S. Cl. CPC H01L 51/502; H01L 33/06; H01L 33/26; H01L 33/56; H01L 31/0352; B82Y 40/00; H05B 33/20; C09K 11/88; C09K 11/02; C01P 2004/64; H01L 33/502

(57) ABSTRACT

An article including a first layer and a second layer; a quantum dot layer disposed between the first layer and the second layer; and wherein the quantum dot layer includes at least one quantum dot having an alloyed core, wherein the alloyed core includes a group III-V semiconductor alloyed with a group II-VI cadmium free compound, and wherein the core and shell emit in a bandwidth less than 50 nanometers.

### TECHNICAL FIELD

The disclosure generally relates to light emitting device and methods and more particularly to methods and structures utilizing a quantum dot film. In particular, the disclosure relates to light emitting devices and methods containing cadmium free quantum dots.

### BACKGROUND

Direct conversion of electricity into light using semiconductor-based light-emitting diodes (LEDs) is widely accepted one of the most promising approaches to more efficient lighting. LEDs demonstrate high brightness, long operational lifetime, and low energy consumption performance that far surpass that of conventional lighting systems such as incandescent and fluorescent light sources. The LED field is currently dominated by semiconductor quantum-well emitters based, e.g., on indium gallium nitride (InGaN)/gallium nitride (GaN)) fabricated by epitaxial methods on crystalline substrates (e.g., sapphire). These structures are highly efficient, reliable, mature and bright, but structural defects at the substrate and semiconductor interface caused by lattice mismatch and heating during operation generally limits such devices to point light source with limited flexible compatibility.

OLEDs are easily amendable to low-temperature, large-area processing, including fabrication on flexible substrates. Synthetic organic chemistry provides essentially an unlimited number of degrees of freedom for tailoring molecular properties to achieve specific functionality, from selective charge transport to color-tunable light emission. The prospect of high-quality lighting sources based on inexpensive “plastic” materials has driven a tremendous amount of research in the area of OLEDs, which in turn has led to the realization of several OLED-based high-tech products such as flat screen televisions and mobile communication devices. Several industrial giants such as Samsung, LG, Sony, and Panasonic are working to develop large-area white-emitting OLEDs both for lighting and display. Despite advances in the OLED field, there are a few drawbacks of this technology that might prevent its widespread use in commercial products. One problem is poor cost-efficiency caused at least in part by the complexity of the necessary device architecture, which requires multiple thermal deposition steps during manufacture. Another problem is their limited stability, particularly for deep-red and blue phosphorescent OLEDs. While improving greatly in recent years, they still do not meet the standards employed in high-end devices.

Chemically synthesized nanocrystal quantum dots (QDs) have emerged as a promising class of emissive materials for low-cost yet efficient LEDs. These luminescent nanomaterials feature size-controlled tunable emission wavelengths and provide improvements in color purity, stability and durability over organic molecules. In addition, as with organic materials, colloidal QDs can be fabricated and processed via inexpensive solution-based techniques compatible with lightweight, flexible substrates. Moreover, similar to other semiconductor materials, colloidal QDs feature almost continuous above-band-edge absorption and a narrow emission spectrum at near-band-edge energies. Distinct from bulk semiconductors, however, the optical spectra of QDs depend directly on their size, Specifically, their emission color can be continuously tuned from the infrared (IR) to ultraviolet (UV) by varying QD size and/or composition. The wide range spectral tunability is combined with high photoluminescence (PL) quantum yields (QYs) that approach unity in well-passivated structures. These unique properties of QDs have been explored for use in various devices such as LEDs, lasers, solar cells, and photo detectors.

It is known that the quantum dots can degrade when they are exposed in air and moisture. In presence of light, oxygen and moisture molecules may cause photo-oxidation and photo-corrosion on the surface of the quantum dots. Once quantum dots react with oxygen and moisture, new defects may be created on the surface of quantum dots. Such defects may result in decreased light emitting of quantum dots.

Quantum dot materials can convert incident light to longer wavelength light with a narrow bandwidth to enhance the color gamut of a display. Quantum dot materials, such as CdSe, CdTe, and CdS contain cadmium (Cd) because of its ability to provide high quantum efficiency at narrow bandwidth. While cadmium is superior in terms of its performance, its toxicity is a concern and increasingly use of cadmium is being restricted. Attempts have been made to substitute other materials for cadmium in quantum dots, but the performance of these materials has not met or surpassed cadmium based quantum dots. In particular, cadmium containing dots produce bandwidths in the range of 25-40 nanometers while cadmium free materials such as InP or CuInS2 show bandwidths of 40-60 nanometers or broader. In addition these materials do not produce the same stability and quantum efficiency as cadmium based quantum dots.

As a result, cadmium free quantum dot materials and related light emitting films that perform similar to or better than cadmium containing quantum dots are needed.

### SUMMARY

The disclosure relates generally to quantum dots, methods of making the same, and articles formed therefrom. The quantum dots of the disclosure may be incorporated as part of an article including but not limited to a film for a light emitting device. According to one example, an article comprises a first layer and a second layer; a quantum dot layer disposed between the first layer and the second layer; and wherein the quantum dot layer includes at least one quantum dot having an alloyed core, wherein the alloyed core includes a group III-V semiconductor alloyed with a group II-VI cadmium free compound, and wherein the core emits a bandwidth less than 50 nanometers.

According to a further example, an article for light emitting devices comprises at least one quantum dot formed from a process comprising disposing a group III-V semiconductor with a group II-VI semiconductor to form an alloyed core, wherein the alloyed core includes a group II-III-V-VI alloyed semiconductor emitting a bandwidth of less than 50 nanometers.

According to a yet another example, a method comprises providing a group III-V semiconductor material with a group II-VI semiconductor material to form an alloyed core comprising a group II-III-V-VI compound having a bandwidth of less than 50 nanometers.

### BRIEF DESCRIPTION OF THE DRAWINGS

The above-mentioned and other features and advantages of this disclosure, and the manner of attaining them, will become apparent and be better understood by reference to the following description of one aspect of the disclosure in conjunction with the accompanying drawings, wherein:

FIG. 1 is a schematic representation of a quantum dot article having group III-V quantum dots and group II-III-V-VI alloyed quantum dots and graphical representations of the luminescence versus wavelength for each.

FIG. 2 is a schematic representation of a composite layered article according to examples of the present disclosure.

FIG. 3 is a schematic representation of a composite layered barrier film structure according to examples of the present disclosure.

FIG. 4 is a method flow diagram according to examples of the present disclosure.

FIG. 5 is a method flow diagram and schematic view according to examples of the present disclosure.

FIG. 6 is a diagram showing simulated results for expected band gap (eV) variations based on a varying ZnSe composition.

### DETAILED DESCRIPTION

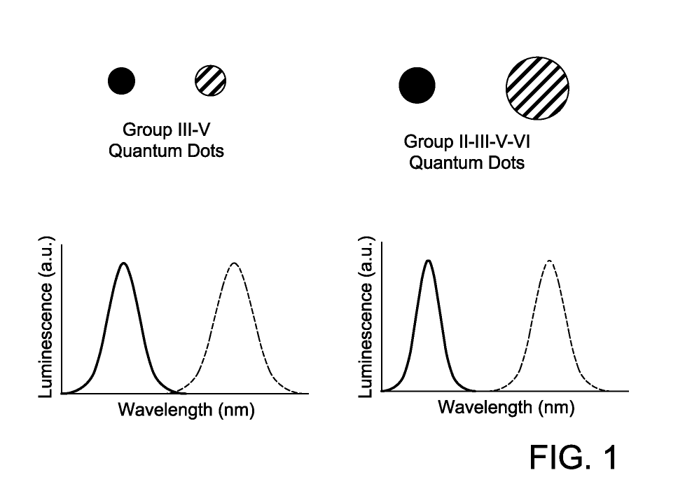

The disclosure relates to quantum dots, methods of forming quantum dots, and related films and other light emitting articles. Overall, the examples of the disclosure described more completely below relate to a cadmium free quantum dot using an alloyed semiconductor nanocrystal structure. The alloyed quantum dots have a medial property between each quantum dot material following the composition. With reference to FIG. 1, Group III-V quantum dots are alloyed with group II-III-V-VI larger bandgap material to narrow the bandwidth despite variations in dot size. The alloyed quantum dot is synthesized via colloidal method in the presence of indium, zinc, selenium, or phosphine source material. While the present disclosure is not so limited, an appreciation of various aspects of the disclosure will be gained through a discussion of the examples provided below.

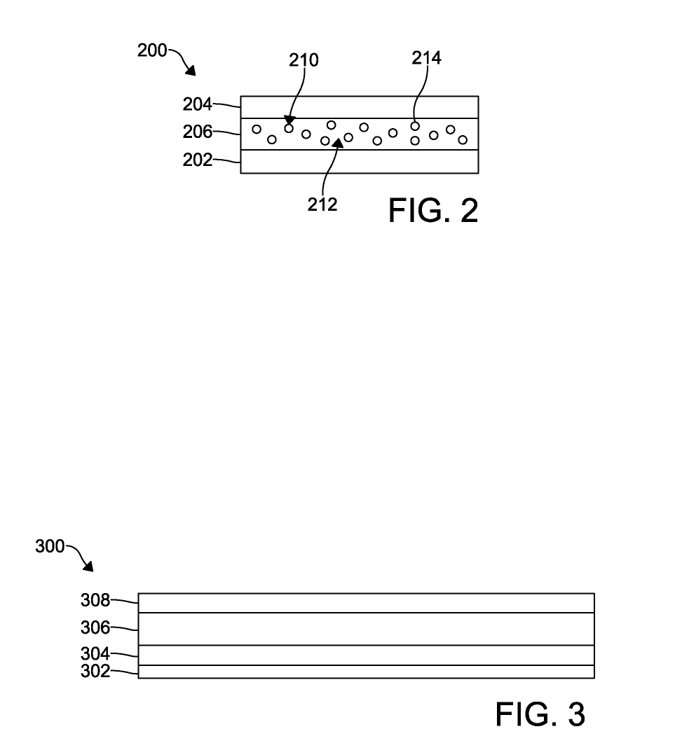

With reference to FIG. 2, a quantum dot film includes a quantum dot solution disposed between first and second layers. The first layer and second layer may be a barrier film. A barrier films inhibit oxygen and moisture from reacting with the quantum dot layer by providing a physical barrier. Alternatively, a protective coating or anti-oxidant layer may be provided to inhibit oxygen and moisture from reacting with the quantum dot layer.

FIG. 2 depicts an illustrative quantum dot (QD) film 200 in more detail. In one or more examples, the QD film 200 includes a first layer 202, a second layer 204, and a quantum dot layer 206 disposed between the first layer 202 and the second layer 204.

The quantum dot layer 206 may include a quantum dot solution 210 dispersed in a polymer material 212 such as acryl type, epoxy type, or silicone type polymers, or combinations thereof. The quantum dot layer 206 may include one or more populations of quantum dot material 214. Exemplary quantum dots or quantum dot material 214 emit green light and red light upon down-conversion of blue primary light from the blue LED to secondary light emitted by the quantum dots. The respective portions of red, green, and blue light can be controlled to achieve a desired white point for the white light emitted by a display device incorporating the quantum dot film article.

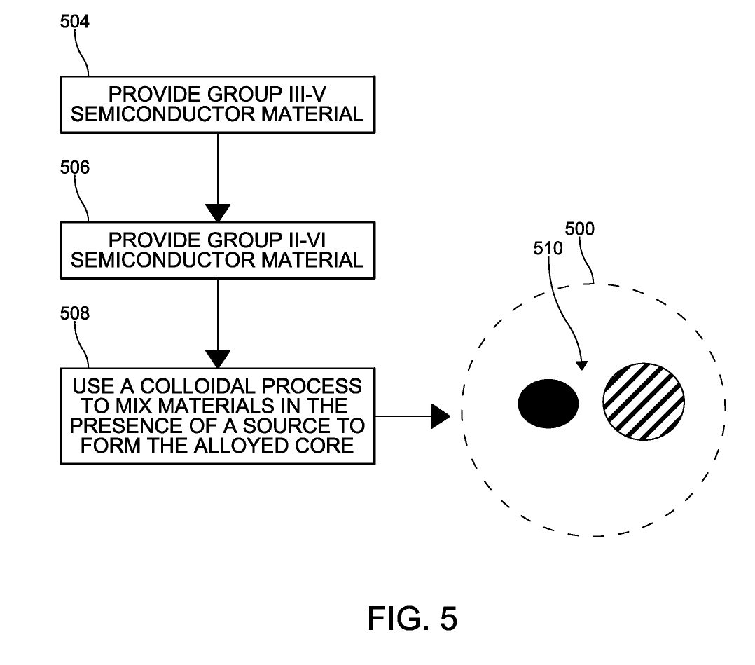

Suitable quantum dots 214 for use in quantum dot film articles described herein include shell/core luminescent nanocrystals including group III-V and II-VI alloyed components in a core. With reference to FIG. 5, example group III-V compound semiconductors are obtained by combining group III elements including but not limited to aluminum Al, Ga, In and zinc Zn with group V elements including but not limited to nitrogen N, phosphorous P, arsenic As, selenium Se, and antimony Sb. Group II-VI semiconductor compounds include a metal from group 2 or 12 of the periodic table. According to the examples, herein, these components do not include cadmium to avoid the toxicity and other practical concerns associated with cadmium Cd. Examples include InP, ZnSe. To obtain bandwidth (FWHM) similar to cadmium containing quantum dot materials, an alloyed semiconductor nanocrystal structure is employed.

The alloyed quantum dots have a medial property between each quantum dot material following their composition. In quantum dots with larger band gap material, the luminescent light is blue shifted. Larger particle size of quantum dots is available for light emission at the same wavelength compared to binary compound quantum dot materials. Besides, the size difference of the quantum dots that emit different color is also bigger. A few angstrom difference of size will not be critical to light emission. In examples according to the disclosure, group III-V quantum dot materials are alloyed with group II, III, IV, V, VI quantum dot materials to form an alloyed core suitable to obtain narrow FWHM luminescent spectra despite non-uniform crystal size.

With reference to FIG. 5, formation of a quantum dot 500 according to one example is schematically depicted. Group III-V semiconductor material is provided with group II-VI semiconductor material at steps 504,506. The alloyed core 510 is synthesized via a colloidal method at 508 in the presence of an indium, zinc, selenium, or phosphine source. The colloidal method includes mixing the group compounds to form a suspension, and applying heat to allow for rearrangement and alloying of compound atoms in promotion of crystal growth.

Group II-III-IV-VI alloys with group III-V quantum dots may be achieved by changing source materials based on the desired compounds. For example, selenium source includes an alkyl selenol (R—Se—H) compound. Using an alkyl selenol as a source compound assists in controlling the formation of the alloy composition.

FIG. 1 shows schematic examples of the synthesized quantum dot(top) and expected photoluminescence (bottom). As shown, alloyed quantum dots exhibit luminescence comparable to the non-alloyed group III-V quantum dots over a narrower light emission band. According to one example of the disclosure, quantum dots have full wave to half maximum (FWHM) bandwidth of less than 50 nanometers. Quantum dots of further examples have FWHM less than 40 nanometers.

Referring to FIG. 2, the quantum dot layer 206 can have any useful amount of quantum dots 214. In many embodiments the quantum dot layer 206 can have from about 0.05 wt % to about 5 wt % quantum dots, however other percentages are possible. The quantum dot layer 206 may optionally include scattering beads or particles. The inclusion of scattering beads or particles results in a longer optical path length and improved quantum dot absorption and efficiency. The particle size is in a range from 50 nm to 10 micrometers, or from 100 nm to 6 micrometers. It is understood that various intervening endpoints in the proposed size ranges may be used. The quantum dot layer 206 may also include fillers such as fumed silica.

The first layer 202 may be formed of any useful material that can protect the quantum dots from environmental conditions such as oxygen and moisture. In the example shown in FIG. 2, first layer 202 is a barrier film 300. Suitable barrier films include polymers, glass or dielectric materials, for example. Suitable barrier film materials include, but are not limited to, polymers such as polyethylene terephthalate (PET); oxides such as silicon oxide, titanium oxide, or aluminum oxide (e.g., SiO₂, Si₂O₃, TiO₂, or Al₂O₃); and suitable combinations thereof.

With reference to FIG. 3, a barrier film 300 of the QD film 200 may include at least two layers of different materials or compositions, such that the multi-layered barrier eliminates or reduces pinhole defect alignment in the barrier layer, providing an effective barrier to oxygen and moisture penetration into the quantum dot layer 206. The QD film 200 may include any suitable material or combination of materials. FIG. 3 illustrates an example barrier layer 300, which may be embodied as at least one of the first layer 202 and second layer 204 (FIG. 2). As shown, the barrier layer 300 may include an inorganic layer 306 disposed on a base substrate 304 (e.g., polymer). Optionally, a functional layer 302, such as a prism or a diffuser, may be provided on substrate 304 opposite inorganic layer 306. The inorganic layer 306 may include inorganic material such as a polysilazane-based polymer, a polysiloxane-based polymer. The inorganic layer may include oxides such as silicon oxide, titanium oxide, or aluminum oxide (e.g., SiO₂, Si₂O₃, TiO₂, or Al₂O₃); and suitable combinations thereof. In certain aspects, a coating 308 may be applied, for example, adjacent the inorganic layer 306. The coating 308 may be an adhesive coating (e.g., organic layer) and may improve the adhesion property with a QD layer, for example.

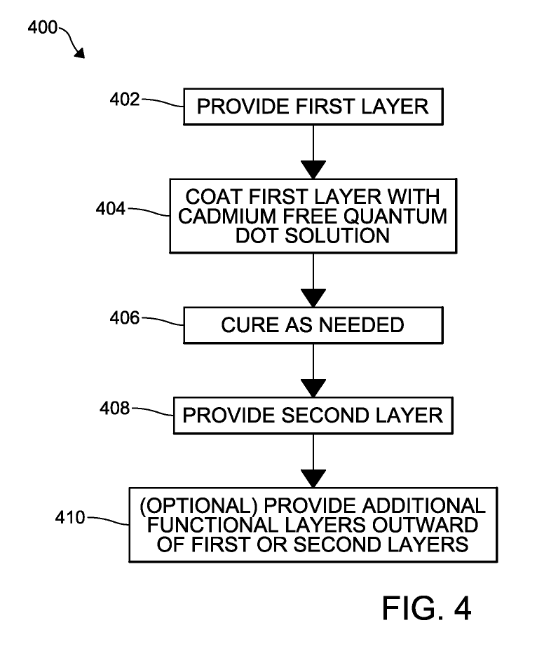

In one or more embodiments, a method of forming a quantum dot film 200 includes coating a quantum dot solution on a first layer 202 and disposing a second layer 204 on the quantum dot layer 206. However, other process may be used. FIG. 4 shows a method according to examples of the present disclosure, generally indicated at 400. The method may comprise providing a first layer at step 402 and disposing a quantum dot solution on a first layer, at step 404. As described, first layer 202 may include a barrier film or other protective layer. The quantum dot solution may be disposed on the first layer 202 using a solution coating process including but not limited to roll coating, gravure coating, knife coating, dip coating, curtain flow coating, spray coating, bar coating, die coating, spin coating or inkjet coating, by using a dispenser, or a combination thereof. At step 406, if needed, the quantum dot solution may be cured to form a quantum dot layer adhered to the first layer 202.

At step 408, a second layer 204 is disposed on the quantum dot layer. If second layer is provided in a liquid form, the second layer may be disposed on the quantum dot layer using one or more coating techniques as described above. Alternatively, solid second layer may be physically applied in any suitable process. As needed, the optional step of curing may be repeated to bond the laminate structure forming film 200. The curing step may include one or more of a radiation curing process including but not limited to a ultraviolet (UV) or electron beam curing process, and a thermal curing process including but not limited to a steam curing process. The first and second layers may inhibit the permeation of at least oxygen and moisture into the quantum dot layer. Optionally film 200 may include additional functional layers applied outward of at least one of first and second layers at step 410. Again, as needed additional curing steps may be provided to form a solid plastic form such as a film 200.

The method can include coating a surface of a solid plastic form with a flowable curable coating composition. The coating can be performed in any suitable manner that forms a coating of the flowable curable coating composition on a surface of the solid plastic form. Wet or transfer coating methods can be used. For example, the coating can be bar coating, spin coating, spray coating, or dipping. Single- or multiple-side coating can be performed.

The solid plastic form can be transparent, opaque, or any one or more colors. The solid plastic form can include any one or more suitable plastics (e.g., as a homogeneous mixture of plastics). In some embodiments, the solid plastic form can include at least one of an acrylonitrile butadiene styrene (ABS) polymer, an acrylic polymer, a celluloid polymer, a cellulose acetate polymer, a cycloolefin copolymer (COC), an ethylene-vinyl acetate (EVA) polymer, an ethylene vinyl alcohol (EVOH) polymer, a fluoroplastic, an ionomer, an acrylic/PVC alloy, a liquid crystal polymer (LCP), a polyacetal polymer (POM or acetal), a polyacrylate polymer, a polymethylmethacrylate polymer (PMMA), a polyacrylonitrile polymer (PAN or acrylonitrile), a polyamide polymer (PA or nylon), a polyamide-imide polymer (PAI), a polyaryletherketone polymer (PAEK), a polybutadiene polymer (PBD), a polybutylene polymer (PB), a polybutylene terephthalate polymer (PBT), a polycaprolactone polymer (PCL), a polychlorotrifluoroethylene polymer (PCTFE), a polytetrafluoroethylene polymer (PTFE), a polyethylene terephthalate polymer (PET), a polycyclohexylene dimethylene terephthalate polymer (PCT), a polycarbonate polymer (PC), a polyhydroxyalkanoate polymer (PHA), a polyketone polymer (PK), a polyester polymer, a polyethylene polymer (PE), a polyetheretherketone polymer (PEEK), a polyetherketoneketone polymer (PEKK), a polyetherketone polymer (PEK), a polyetherimide polymer (PEI), a polyethersulfone polymer (PES), a polyethylenechlorinate polymer (PEC), a polyimide polymer (PI), a polylactic acid polymer (PLA), a polymethylpentene polymer (PMP), a polyphenylene oxide polymer (PPO), a polyphenylene sulfide polymer (PPS), a polyphthalamide polymer (PPA), a polypropylene polymer, a polystyrene polymer (PS), a polysulfone polymer (PSU), a polytrimethylene terephthalate polymer (PTT), a polyurethane polymer (PU), a polyvinyl acetate polymer (PVA), a polyvinyl chloride polymer (PVC), a polyvinylidene chloride polymer (PVDC), a polyamideimide polymer (PAI), a polyarylate polymer, a polyoxymethylene polymer (POM), and a styrene-acrylonitrile polymer (SAN). In some embodiments, the solid plastic form includes at least one of polycarbonate polymer (PC) and polymethylmethacrylate polymer (PMMA). The solid plastic form can include a blend of PC and PMMA.

The solid plastic form can include one type of polycarbonate or multiple types of polycarbonate. The polycarbonate can be made via interfacial polymerization (e.g., reaction of bisphenol with phosgene at an interface between an organic solution such as methylene chloride and a caustic aqueous solution) or melt polymerization (e.g., transesterification and/or polycondensation of monomers or oligomers above the melt temperature of the reaction mass). Although the reaction conditions for interfacial polymerization may vary, in an example the procedure can include dissolving or dispersing a dihydric phenol reactant in aqueous caustic soda or potash, adding the resulting mixture to a suitable water-immiscible solvent medium, and contacting the reactants with a carbonate precursor e.g., phosgene) in the presence of a catalyst such as triethylamine or a phase transfer catalyst, under controlled pH conditions, e.g., about 8 to about 10. The most commonly used water-immiscible solvents include methylene chloride, 1,2-dichloroethane, chlorobenzene, toluene, and the like.

Alternatively, melt processes may be used to make the polycarbonates. Generally, in the melt polymerization process, polycarbonates may be prepared by co-reacting, in a molten state, the dihydroxy reactant(s) and a diaryl carbonate ester, such as diphenyl carbonate, in the presence of a transesterification catalyst in a mixer, twin screw extruder, or the like, to form a uniform dispersion. Volatile monohydric phenol can be removed from the molten reactants by distillation and the polymer can be isolated as a molten residue. In some embodiments, a melt process for making polycarbonates uses a diaryl carbonate ester having electron-withdrawing substituents on the amyl groups, such as bis(4-nitrophenyl)carbonate, bis(2-chlorophenyl)carbonate, bis(4-chlorophenyl)carbonate, bis(methyl salicyl) carbonate, bis(4-methylcarboxylphenyl)carbonate, bis(2-acetylphenyl)carboxylate, bis(4-acetylphenyl)carboxylate, or a combination thereof. In addition, transesterification catalysts for use may include phase transfer catalysts such as tetrabutylammonium hydroxide, methyltributylammonium hydroxide, tetrabutylammonium acetate, tetrabutylphosphonium hydroxide, tetrabutylphosphonium acetate, tetrabutylphosphonium phenolate, or a combination thereof.

The one or more polycarbonates can be about 50 wt % to about 100 wt % of the solid plastic form, such as about 50 wt % or less, or about 55 wt %, 60, 65, 70, 75, 80, 85, 90, 95, 96, 97, 98, 99, 99.9 wt %, or about 99.99 wt % or more. In various embodiments, the polycarbonate can include a repeating group having the structure:

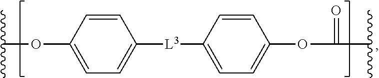

Each phenyl ring in the structure is independently substituted or unsubstituted. The variable L³ is chosen from —S(O)₂— and substituted or unsubstituted (C₁-C₂₀)hydrocarbylene. In various embodiments, the polycarbonate can be derived from bisphenol A, such that the polycarbonate includes a repeating group having the structure:

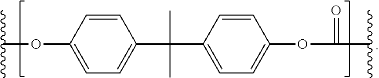

The solid plastic form can include a filler, such as one filler or multiple fillers. The filler can be any suitable type of filler. The filler can be homogeneously distributed in the solid plastic form. The one or more fillers can form about 0.001 wt % to about 50 wt % of the solid plastic form, or about 0.01 wt % to about 30 wt %, or about 0.001 wt % or less, or about 0.01 wt %, 0.1, 1, 2, 3, 4, 5, 10, 15, 20, 25, 30, 35, 40, 45 wt %, or about 50 wt % or more. The filler can be fibrous or particulate. The filler can be aluminum silicate (mullite), synthetic calcium silicate, zirconium silicate, fused silica, crystalline silica graphite, natural silica sand, or the like; boron powders; oxides such as TiO₂, aluminum oxide, magnesium oxide, or the like; calcium sulfate (as its anhydride, dehydrate or trihydrate); calcium carbonates such as chalk, limestone, marble, synthetic precipitated calcium carbonates, or the like; talc, including fibrous, modular, needle shaped, lamellar talc, or the like; wollastonite; surface-treated wollastonite; glass spheres such as hollow and solid glass spheres; kaolin; single crystal fibers or “whiskers” such as silicon carbide, alumina, boron carbide, iron, nickel, copper, or the like; fibers (including continuous and chopped fibers) such as asbestos, carbon fibers, glass fibers; sulfides such as molybdenum sulfide, zinc sulfide, or the like; barium compounds; metals and metal oxides such as particulate or fibrous materials; flaked fillers; fibrous fillers, for example short inorganic fibers such as those derived from blends including at least one of aluminum silicates, aluminum oxides, magnesium oxides, and calcium sulfate hemihydrate or the like; natural fillers and reinforcements; organic fillers such as polytetrafluoroethylene, reinforcing organic fibrous fillers formed from organic polymers capable of forming fibers such as poly(ether ketone), polyimide, polybenzoxazole, poly(phenylene sulfide), polyesters, polyethylene, aromatic polyamides, aromatic polyimides, polyetherimides, polytetrafluoroethylene, acrylic resins, poly(vinyl alcohol) or the like; or combinations including at least one of the foregoing fillers. The filler can be selected from glass fibers, carbon fibers, a mineral fillers, or combinations thereof. The filler can be glass fibers.

The glass fibers can be selected from E-glass, S-glass, AR-glass, T-glass, D-glass, R-glass, and combinations thereof. The glass fibers used can be selected from E-glass, S-glass, and combinations thereof. High-strength glass is generally known as S-type glass in the United States, R-glass in Europe, and T-glass in Japan. High-strength glass has appreciably higher amounts of silica oxide, aluminum oxide and magnesium oxide than E-glass. S-2 glass is approximately 40-70% stronger than E-glass. The glass fibers can be made by standard processes, e.g., by steam or air blowing, flame blowing, and mechanical pulling.

The glass fibers can be sized or unsized. Sized glass fibers are coated on their surfaces with a sizing composition selected for compatibility with the polycarbonate. The sizing composition facilitates wet-out and wet-through of the polycarbonate on the fiber strands and assists in attaining desired physical properties in the polycarbonate composition. The glass fibers can be sized with a coating agent. The coating agent can be present in an amount from about 0.1 wt % to about 5 wt %, or about 0.1 wt % to about 2 wt %, based on the weight of the glass fibers.

In preparing the glass fibers, a number of filaments can be formed simultaneously, sized with the coating agent and then bundled into what is called a strand. Alternatively the strand itself may be first formed of filaments and then sized. The amount of sizing employed is generally that amount which is sufficient to bind the glass filaments into a continuous strand and can be about 0.1 to about 5 wt %, about 0.1 to 2 wt %, or about 1 wt %, based on the weight of the glass fibers.

The glass fibers can be continuous or chopped. Glass fibers in the form of chopped strands may have a length of about 0.3 millimeters (mm) to about 10 centimeters (cm), about 0.5 cm to about 5 cm, or about 1.0 mm to about 2.5 cm. In various further aspects, the glass fibers can have a length of about 0.2 mm to about 20 mm, about 0.2 mm to about 10 mm, or about 0.7 mm to about 7 mm, 1 mm or longer, or 2 mm or longer. The glass fibers can have a round (or circular), flat, or irregular cross-section. The diameter of the glass fibers can be about 1 micrometers (μm) to about 15 μm, about 4 to about 10 μm, about 1 μm to about 10 μm, or about 7 μm to about 10 μm.

The solid plastic form can include a polyester. The polyester can be any suitable polyester. The polyester can be chosen from aromatic polyesters, poly(alkylene esters) including poly(alkylene arylates) (e.g., poly(alkylene terephthalates)), and poly(cycloalkylene diesters) (e.g., poly(cycloghexanedimethylene terephthalate) (PCT), or poly(1,4-cyclohexane-dimethanol-1,4-cyclohexanedicarboxylate) (PCCD)), and resourcinol-based aryl polyesters. The polyester can be poly(isophthalate-terephthalate-resorcinol)esters, poly(isophthalate-terephthalate-bisphenol A)esters, poly[(isophthalate-terephthalate-resorcinol)ester-co-(isophthalate-terephthalate-bisphenol A)]ester, or a combination including at least one of these. Examples of poly(alkylene terephthalates) include poly(ethylene terephthalate) (PET), poly(1,4-butylene terephthalate) (PBT), and poly(propylene terephthalate) (PPT). Also useful are poly(alkylene naphthoates), such as poly(ethylene naphthanoate) (PEN), and poly(butylene naphthanoate) (PBN). Copolymers including alkylene terephthalate repeating ester units with other ester groups can also be useful. Useful ester units can include different alkylene terephthalate units, which can be present in the polymer chain as individual units, or as blocks of poly(alkylene terephthalates). Specific examples of such copolymers include poly(cyclohexanedimethylene terephthalate)-co-poly(ethylene terephthalate), abbreviated as PETG where the polymer includes greater than or equal to 50 mol % of poly(ethylene terephthalate), and abbreviated as PCTG where the polymer includes greater than 50 mol % of poly(1,4-cyclohexanedimethylene terephthalate). The polyester can be substantially homogeneously distributed in the solid plastic form. The solid plastic form can include one type of polyester or multiple types of polyester. The one or more polyesters can form any suitable proportion of the solid plastic form, such as about 0.001 wt % to about 50 wt % of the solid plastic form, about 0.01 wt % to about 30 wt %, or about 0.001 wt % or less, or about 0.01 wt %, 0.1, 1, 2, 3, 4, 5, 6, 8, 10, 12, 14, 16, 18, 20, 22, 24, 26, 28, 30, 35, 40, 45 wt %, or about 50 wt % or more. The polyester can includes a repeating unit having the structure:

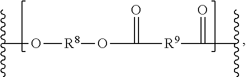

The variables R⁸ and R⁹ can be independently substituted or unsubstituted (C₁-C₂₀)hydrocarbylene. The variables R⁸ and R⁹ can be cycloalkylene-containing groups or aryl-containing groups. The variables R⁸ and R⁹ can be independently substituted or unsubstituted phenyl, or substituted or unsubstituted —(C₀-C₁₀)hydrocarbyl-(C₄-C₁₀)cycloalkyl-(C₀-C₁₀)hydrocarbyl-. The variables R⁸ and R⁹ can both be cycloalkylene-containing groups. The variables R⁸ and R⁹ can independently have the structure:

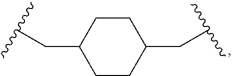 [SMILES: *CC1CCC(C*)CC1]

wherein the cyclohexylene can be substituted in a cis or trans fashion. In some examples, R9 can be a para-substituted phenyl, such that R⁹ appears in the polyester structure as:

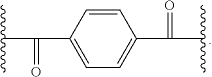 [SMILES: *C(=O)c1ccc(C(*)=O)cc1]

The solid plastic form can have any suitable shape and size. In some embodiments, the solid plastic form is a sheet having any suitable thickness, such as a thickness of about 25 microns to about 50,000 microns, about 25 microns to about 15,000 microns, about 60 microns to about 800 microns, or about 25 microns or less, or about 50, 75, 100, 150, 200, 250, 300, 400, 500, 600, 700, 800, 900, 1,000, 1,500, 2,000, 3,000, 4,000, 5,000, 6,000, 8,000, 10,000, 12,000, 14,000, 15,000, 20,000, 25,000, 30,000, 40,000, or about 50,000 microns or more.

The flowable curable coating composition can include a) an alicyclic epoxy group-containing siloxane resin having a weight average molecular weight of about 1,000 to about 4,000 and a (M_{w}/Mₙ) of about 1.05 to about 1.4, b) an epoxy-functional organosiloxane and an organosiloxane comprising a isocyanate group or an isocyanurate group, or both a) and b).

The epoxy-functional organosiloxane can have the structure:

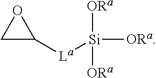

At each occurrence, R^{a} can be independently substituted or unsubstituted (C₁-C₁₀)alkyl. At each occurrence, the variable R^{a} can be independently unsubstituted (C₁-C₆)alkyl. The variable L^{a} can be substituted or unsubstituted (C₁-C₃₀)hydrocarbyl interrupted by 0, 1, 2, or 3 groups independently chosen from —O—, —S—, substituted or unsubstituted —NH—, —(Si(OR^{a})²)ₙ₁—, —(O—CH₂—CH₂)ₙ₁—, and —(O—CH₂—CH₂—CH₂)ₙ₁—, wherein n1 can be about 1 to about 1,000 (e.g., 1-100, 1-50, 1-10, 1, 2, 3, 4, 5, 6, 8, 10, 12, 14, 16, 18, 20, 25, 30, 40, 50, 75, 100, 200, 250, 500, 750, 1,000). The variable L^{a} can be an unsubstituted (C₁-C₃₀)hydrocarbyl interrupted by 0, 1, 2, or 3 groups independently chosen from —O— and —S—. The epoxy-functional organosiloxane can be 2-(3,4-epoxycyclohexyl)ethyltrimethoxysilane, 3-glycidoxypropyl methyldimethoxysilane, 3-glycidoxypropyl trimethoxysilane, 3-glycidoxypropyl methyldiethoxysilane, or 3-glycidoxypropyl triethoxysilane. The flowable curable resin composition can include one epoxy-functional organosiloxane, or multiple epoxy-functional organosiloxanes. The one or more epoxy-functional organosiloxanes can be any suitable proportion of the flowable curable resin composition such as about 0.01 wt % to about 100 wt %, 10 wt % to about 100 wt %, about 50 wt % to about 99.9 wt %, or about 0.01 wt % or less, or about 0.1 wt %, 1, 2, 3, 4, 5, 6, 8, 10, 12, 14, 15, 20, 25, 30, 35, 40, 45, 50, 55, 60, 65, 70, 75, 80, 85, 90, 95, 96, 97, 98, 99, 99.9, or about 99.99 wt %.

The organosiloxane including an isocyanate group can have the structure (R^{b})₄₋ₚSi(R^{c})ₚ. The variable p can be 1 to 4 (e.g., 1, 2, 3, or 4). At each occurrence, R^{b} can be independently chosen from substituted or unsubstituted (C₁-C₁₀)alkyl and substituted or unsubstituted (C₁-C₁₀)alkoxy. At each occurrence, R^{b} can be independently chosen from unsubstituted (C₁-C₆)alkyl and unsubstituted (C₁-C₆)alkoxy. At each occurrence, R^{c} can be -L^{b}-NCO, wherein L^{b} can be a substituted or unsubstituted (C₁-C₃₀)hydrocarbyl interrupted by 0, 1, 2, or 3 groups independently chosen from —O—, —S—, substituted or unsubstituted —NH—, —(Si(OR^{b})₂)ₙ₂-, —(O—CH₂—CH₂)ₙ₂—, and —(O—CH₂—CH₂—CH₂)ₙ₂—, wherein n2 can be about 1 to about 1,000 (e.g., 1-100, 1-50, 1-10, 1, 2, 3, 4, 5, 6, 8, 10, 12, 14, 16, 18, 20, 25, 30, 40, 50, 75, 100, 200, 250, 500, 750, 1,000). At each occurrence, Le can be an unsubstituted (C₁-C₃₀)hydrocarbyl interrupted by 0, 1, 2, or 3 groups independently chosen from —O— and —S—. The organosiloxane including the isocyanate group can be 3-isocyanatepropyltriethoxysilane. The flowable curable resin composition can include one or more than one organosiloxane including an isocyanate group. The one or more organosiloxanes including an isocyanate group can form any suitable proportion of the flowable curable resin composition, such as about 0.01 wt % to about 100 wt %, 10 wt % to about 100 wt %, about 50 wt % to about 99.9 wt %, or about 0.01 wt % or less, or about 0.1 wt %, 1, 2, 3, 4, 5, 6, 8, 10, 12, 14, 15, 20, 25, 30, 35, 40, 45, 50, 55, 60, 65, 70, 75, 80, 85, 90, 95, 96, 97, 98, 99, 99.9, or about 99.99 wt %.

The organosiloxane including an isocyanurate group can have the structure:

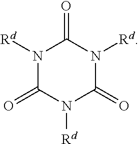

At each occurrence, R^{d} can be chosen from —H and -L^{c}-Si(R^{e})₃, wherein at least one R^{d} is -L^{c}-Si(R^{e})₃. At each occurrence, R^{d} can be -L^{c}-Si(R^{e})₃. At each occurrence, L^{c} can be independently a substituted or unsubstituted (C₁-C₃₀)hydrocarbyl interrupted by 0, 1, 2, or 3 groups independently chosen from —O—, —S—, substituted or unsubstituted —NH—, —(Si(R^{e})₂)ₙ₃—, —(O—CH₂—CH₂)ₙ₃—, and —(O—CH₂—CH₂—CH₂)ₙ₃—, wherein n3 can be about 1 to about 1,000 (e.g., 1-100, 1-50, 1-10, 1, 2, 3, 4, 5, 6, 8, 10, 12, 14, 16, 18, 20, 25, 30, 40, 50, 75, 100, 200, 250, 500, 750, 1,000). At each occurrence, Le can be an unsubstituted (C₁-C₃₀)hydrocarbyl interrupted by 0, 1, 2, or 3 groups independently chosen from —O— and —S—. At each occurrence, R^{e} can be chosen from substituted or unsubstituted (C₁-C₁₀)alkyl and substituted or unsubstituted (C₁-C₁₀)alkoxy. At each occurrence, R^{e} can be independently chosen from unsubstituted (C₁-C₆)alkyl and unsubstituted (C₁-C₆)alkoxy. The organosiloxane including the isocyanate group or isocyanurate group can be tris-[3-(trimethoxysilylpropyl)-isocyanurate. The flowable curable resin composition can include one or multiple organosiloxanes including an isocyanurate group. Any suitable proportion of the flowable curable resin composition can be the one or more organosiloxanes including an isocyanurate group, such as about 0.01 wt % to about 100 wt %, 10 wt % to about 100 wt %, about 50 wt % to about 99.9 wt %, or about 0.01 wt % or less, or about 0.1 wt %, 1, 2, 3, 4, 5, 6, 8, 10, 12, 14, 15, 20, 25, 30, 35, 40, 45, 50, 55, 60, 65, 70, 75, 80, 85, 90, 95, 96, 97, 98, 99, 99.9, or about 99.99 wt %.

The flowable curable resin composition can include a bis(organosiloxane)-functional amine. In some embodiments, the flowable curable resin composition includes an epoxy-functional organosiloxane, an organosiloxane comprising a isocyanate group or an isocyanurate group, and a bis(organosiloxane)-functional amine. The bis(organosiloxane)-functional amine can have the structure R^{f}₃Si-L^{d}-NH-L^{d}-SiR^{f}₃. At each occurrence, R^{f} can be chosen from substituted or unsubstituted (C₁-C₁₀)alkyl and substituted or unsubstituted (C₁-C₁₀)alkoxy. At each occurrence, R^{f} can be independently chosen from unsubstituted (C₁-C₆)alkyl and unsubstituted (C₁-C₆)alkoxy. At each occurrence, L^{d} can be independently a substituted or unsubstituted (C₁-C₃₀)hydrocarbyl interrupted by 0, 1, 2, or 3 groups independently chosen from —O—, —S—, substituted or unsubstituted —NH—, —(Si(R^{f})₂)ₙ₄—, —(O—CH₂—CH₂)ₙ₄—, and —(O—CH₂—CH₂—CH₂)ₙ₄—, wherein n4 can be about 1 to about 1,000 (e.g., 1-100, 1-50, 1-10, 1, 2, 3, 4, 5, 6, 8, 10, 12, 14, 16, 18, 20, 25, 30, 40, 50, 75, 100, 200, 250, 500, 750, 1,000). At each occurrence, L^{d} can be an unsubstituted (C₁-C₃₀)hydrocarbyl interrupted by 0, 1, 2, or 3 groups independently chosen from —O— and —S—. The bis(organosiloxane)-functional amine can be bis(triethoxysilylpropyl)amine, bis(trimethoxysilylpropyl)amine, or bis(methyldiethoxysilylpropyl) amine. The flowable curable resin composition can include one or more bis(organosiloxane)-functional amines. The one or more bis(organosiloxane)-functional amines can form any suitable proportion of the flowable curable resin composition, such as about 0.01 wt % to about 100 wt %, 10 wt % to about 100 wt %, about 50 wt % to about 99.9 wt %, or about 0.01 wt % or less, or about 0.1 wt %, 1, 2, 3, 4, 5, 6, 8, 10, 12, 14, 15, 20, 25, 30, 35, 40, 45, 50, 55, 60, 65, 70, 75, 80, 85, 90, 95, 96, 97, 98, 99, 99.9, or about 99.99 wt %.

The method can include performing a hydrolysis and condensation reaction using water and a catalyst to form a sol (e.g., colloidal suspension), releasing alcohol or water. The sol can include the flowable curable resin composition. Coating the surface of the solid plastic form can include coating the solid plastic form with the sol. Curing the curable coating composition can include curing the sol on the plastic form, to provide the hardened film (e.g., gel) on the solid plastic form surface.

The flowable curable coating composition can include an alicyclic epoxy group-containing siloxane resin. The flowable curable coating composition can include one type of alicyclic epoxy group-containing siloxane resin or multiple types of such resin. The one or more alicyclic epoxy group-containing siloxane resin can form any suitable proportion of the flowable curable coating composition, such as about 0.01 wt % to about 100 wt %, 10 wt % to about 100 wt %, about 50 wt % to about 99.9 wt %, or about 0.01 wt % or less, or about 0.1 wt %, 1, 2, 3, 4, 5, 6, 8, 10, 12, 14, 15, 20, 25, 30, 35, 40, 45, 50, 55, 60, 65, 70, 75, 80, 85, 90, 95, 96, 97, 98, 99, 99.9, or about 99.99 wt %. The siloxane resin can have a weight average molecular weight of about 1,000 to about 4,000 (e.g., about 1,000, 1,200, 1,400, 1,600, 1,800, 2,000, 2,200, 2,400, 2,600, 2,800, 3,000, 3,200, 3,400, 3,600, 3,800, or 4,000) and a (M_{w}/Mₙ) (i.e., weight average molecular weight divided by number average molecular weight, also referred to as polydispersity, a measure of the heterogeneity of sizes of molecules in the mixture) of about 1.05 to about 1.4 (e.g., about 1.05, 1.2, 1.4, 1.6, 1.8, 2.0, 2.2, 2.4, 2.6, 2.8, 3.0, 3.2, 3.4, 3.6, 3.8, or about 4.0 or more).

The siloxane resin can be prepared by hydrolysis and condensation, in the presence of water and an optional catalyst, of (i) an alkoxysilane including an alicyclic epoxy group and an alkoxy group having the structure R¹ₙSi(OR²)₄-n alone, wherein R¹ is (C₃-C₆)cycloalkyl(C₁-C₆)alkyl wherein the cycloalkyl group includes an epoxy group, R² is (C₁-C₇)alkyl, and n is 1-3, or (ii) the alkoxysilane having the structure R¹ₙSi(OR²)₄-n and an alkoxysilane having the structure R³ₘSi(OR⁴)₄₋ₘ, wherein R³ is chosen from (C₁-C₂₀)alkyl, (C₃-C₅)cycloalkyl, (C₂-C₂₀)alkenyl, (C₂-C₂₀)alkynyl, (C₆-C₂₀)aryl, an acryl group, a methacyl group, a halogen group, an amino group, a mercapto group, an ether group, an ester group, a carbonayl group, a carboxyl group, a vinyl group, a nitro group, a sulfone group, and an alkyd group, R⁴ is (C₁-C₇)alkyl, and m is 0 to 3. The alkoxysilxane having the structure R¹ₙSi(OR²)₄₋ₙ can be 2-(3,4-epoxycyclohexyl)ethyltrimethoxysilane or 2-(3,4-epoxycyclohexyl)ethyltriethoxysilane. The alkoxysilane having the structure R³ₘSi(OR⁴)₄₋ₘ can be one or more chosen from tetramethoxysilane, tetraethoxysilane, methyltrimethoxysilane, methyltriethoxysilane, methyltripropoxysilane, dimethyldimethoxysilane, dimethyldiethoxysilane, phenyltrimethoxysilane, phenyltriethoxysilane, diphenyldimethoxysilane, diphenyldiethoxysilane, triphenylmethoxysilane, triphenylethoxysilane, ethyltriethoxysilane, propylethyltrimethoxysilane, vinyltrimethoxysilane, vinyltriethoxysilane, vinyltripropoxysilane, N-(3-acryloxy-2-hydroxypropyl)-3-aminopropyltrimethoxysilane, N-(3-acryloxy-2-hydroxypropyl)-3-aminopropyltriethoxysilane, N-(3-acryloxy-2-hydroxypropyl)-3-aminopropyltripropoxysilane, 3-acryloxypropylmethylbis (trimethoxy) silane, 3-acryloxypropyltrimethoxysilane, 3-acryloxypropyltriethoxysilane, 3-acryloxypropyltripropoxysilane, 3-(meth)acryloxypropyltrimethoxysilane, 3-(meth)acryloxypropyltriethoxysilane, 3-(meth)acryloxypropyltripropoxysilane, N-(aminoethyl-3-aminopropyl)trimethoxysilane, N-(2-aminoethyl-3-aminopropyl)triethoxysilane, 3-aminopropyltrimethoxysilane, 3-aminopropyltriethoxysilane, chloropropyltrimethoxysilane, chloropropyltriethoxysilane, and heptadecafluorodecyltrimethoxysilane.

The flowable curable coating composition can further include a reactive monomer capable of reacting with the alicyclic epoxy group to form crosslinking. The flowable curable coating composition can include one such monomer or multiple such monomers. The one or more reactive monomers can form any suitable proportion of the flowable curable coating composition, such as about 0.001 wt % to about 30 wt %, or about 0.01 wt % to about 10 wt %, or about 0.001 wt % or less, or about 0.01 wt %, 0.1, 1, 2, 3, 4, 5, 6, 8, 10, 12, 14, 16, 18, 20, 22, 24, 26, 28, or about 30 wt % or more. The one or more reactive monomer can be present in any suitable weight ratio to the epoxy-containing siloxane resin, such as about 1:1000 to about 1:10, or about 1:1000 or less, or about 1:500, 1:250, 1:200, 1:150, 1:100, 1:80, 1:60, 1:40, 1:20, or about 1:10 or more. The reactive monomer can be an acid anhydride monomer, an oxetane monomer, or a monomer having an alicyclic epoxy group as a (C₃-C₆)cycloalkyl group. The acid anhydride monomer can be one or more chosen from phthalic anhydride, tetrahydrophthalic anhydride, hexahydrophthalic anhydride, nadic methyl anhydride, chlorendic anhydride, and pyromellitic anhydride. The oxetane monomer can be one or more chosen from 3-ethyl-3-hydroxymethyloxetane, 2-ethylhexyloxetane, xylene bis oxetane, and 3-ethyl-3[[3-ethyloxetan-3-yl]methoxy]oxetane. The reactive monomer having an alicyclic epoxy group can be one or more chosen from 4-vinylcycloghexene dioxide, cyclohexene vinyl monoxide, (3,4-epoxycyclohexyl)methyl 3,4-epoxycyclohexylcarboxylate, 3,4-epoxycyclohexylmethyl methacrylate, and bis(3,4-epoxycyclohexylmethyl)adipate.

In various embodiments, one or more catalysts are present. In other embodiments, the flowable curable coating composition can be free of catalyst. The catalyst can be any suitable catalyst, such as acidic catalysts, basic catalysts, ion exchange resins, and combinations thereof. For example, the catalyst can be hydrochloric acid, acetic acid, hydrogen fluoride, nitric acid, sulfuric acid, chlorosulfonic acid, iodic acid, pyrophosphoric acid, ammonia, potassium hydroxide, sodium hydroxide, barium hydroxide, imidazole, and combinations thereof.

The curable flowable coating composition can include one or more organic solvents, such as in an amount of about 0.01 to about 10 parts by weight, based on 100 parts by weight of the siloxane resin, or about 0.1 to about 10 parts by weight. The one or more solvents can be about 0.001 wt % to about 50 wt % of the curable flowable coating composition, about 0.01 wt % to about 30 wt %, about 30 wt % to about 70 wt %, or about 0.001 wt % or less, or about 0.01 wt %, 0.1, 1, 2, 3, 4, 5, 6, 8, 10, 12, 14, 16, 18, 20, 22, 24, 26, 28, 30, 35, 40, 45 wt %, or about 50 wt % or more.

The flowable curable coating composition can further includes one or more polymerization initiators chosen from UV initiators, thermal initiators, onium salts, organometallic salts, amines, and imidazoles in an amount of about 0.01 to about 10 parts by weight, based on 100 parts by weight of the siloxane resin, or about 0.1 to about 10 parts by weight. The one or more polymerization initiators can be about 0.001 wt % to about 50 wt % of the curable flowable coating composition, about 0.01 wt % to about 30 wt %, or about 0.001 wt % or less, or about 0.01 wt %, 0.1, 1, 2, 3, 4, 5, 6, 8, 10, 12, 14, 16, 18, 20, 22, 24, 26, 28, 30, 35, 40, 45 wt %, or about 50 wt % or more.

The flowable curable coating composition can further include one or more additives, such as chosen from an antioxidant, a leveling agent, an antifogging agent, an antifouling agent, and a coating control agent. According to the disclosure, a scavenger is provided within the flowable curable coating composition when forming a protective layer. The scavenger inhibits at least one of oxygen and moisture from contacting the quantum dot layer and reacting with it.

The method can also include curing the curable coating composition, to provide a hardened film on the solid plastic form surface. The curing can be any suitable curing. The curing can be thermal curing. The curing can be UV curing. The curing can be a combination of thermal and UV curing (e.g., in parallel or sequential).

The hardened film on the solid plastic form can have any suitable thickness, such as about 1 micron to about 1,000 microns, about 1 micron to about 100 microns, about 5 microns to about 75 microns, or about 1 micron, 2, 3, 4, 5, 6, 8, 10, 12, 14, 16, 18, 20, 25, 30, 35, 40, 45, 50, 55, 60, 65, 70, 75, 80, 85, 90, 95, 100, 200, 500, 750, or about 1,000 microns or more.

The hardened film on the solid plastic form surface can have any suitable hardness.

For example, the hardened film on the solid plastic form surface can have a hardness, namely a pencil hardness of about 3B to about 9H, or about HB to about 8H, or about 3B or less, or about 2B, B, HB, F, H, 2H, 3H, 4H, 5H, 6H, 7H, 8H, or about 9H or more. Pencil hardness is a measure of the hardness of a material on a scale ranging from 9H (hardest) to 9B (softest). In general, the pencil hardness scale is 9H (hardest), 8H, 7H, 6H, 5H, 4H, 3H, 2H, H, F, HB (medium), B, 2B, 3B, 4B, 5B, 6B, 7B, 8B, and 9B (softest), for example, at a 700 grams (g) or 1 kg load. In an aspect, the hardened film on the solid plastic form surface may have a pencil hardness of about 3B to about 9H, or about HB to about 8H, or about 3B or less, or about 2B, B, HB, F, H, 2H, 3H, 4H, 5H, 6H, 7H, 8H, or about 9H or more. Pencil hardness may be determined according to ASTM D3363 at a 1 kg load, for example.

### Aspects

The present disclosure comprises at least the following aspects.

Aspect 1A. An article comprising a first layer and a second layer; a quantum dot layer disposed between the first layer and the second layer; and wherein the quantum dot layer includes at least one quantum dot having an alloyed core, wherein the alloyed core includes a group III-V semiconductor alloyed with a group II-VI cadmium free compound, and wherein the core emits a bandwidth less than 50 nanometers.

Aspect 1B. An article consisting essentially of: a first layer and a second layer; a quantum dot layer disposed between the first layer and the second layer; and wherein the quantum dot layer includes at least one quantum dot having an alloyed core, wherein the alloyed core includes a group III-V semiconductor alloyed with a group II-VI cadmium free compound, and wherein the core emits a bandwidth less than 50 nanometers.

Aspect 1B. An article consisting of: a first layer and a second layer; a quantum dot layer disposed between the first layer and the second layer; and wherein the quantum dot layer includes at least one quantum dot having an alloyed core, wherein the alloyed core includes a group III-V semiconductor alloyed with a group II-VI cadmium free compound, and wherein the core emits a bandwidth less than 50 nanometers.

Aspect 2. The article of any of aspects 1A-1C, wherein the bandwidth is less than 40 nanometers.

Aspect 3. The article of any one aspects 1A-2, wherein alloyed core is InP.

Aspect 4. The article of any one aspects 1A-2, wherein the alloyed core is FeSe.

Aspect 5. The article of aspects 1A-3, wherein the first layer and the second layer each include a barrier film.

Aspect 6. The article of any one of aspects 1A-5, further comprising a functional layer provided outward of the at least one of the first layer and second layer.

Aspect 7. The article of any one of aspects 1A-6, wherein the functional layer is a diffuser.

Aspect 9. The article of any one of aspects 1A-7, wherein the quantum dot layer is disposed on the first layer using a solution coating process.

Aspect 10. A light emitting device comprising the article of any one of aspects 1-9.

Aspect 11A. An article for light emitting devices comprising: at least one quantum dot formed from a process comprising disposing a group III-V semiconductor with a group II-VI semiconductor to form an alloyed core, wherein the alloyed core includes a group V-VI alloyed semiconductor emitting a bandwidth of less than 50 nanometers.

Aspect 11B. An article for light emitting devices consisting essentially of: at least one quantum dot formed from a process comprising disposing a group III-V semiconductor with a group II-VI semiconductor to form an alloyed core, wherein the alloyed core includes a group II-III-V-VI alloyed semiconductor emitting a bandwidth of less than 50 nanometers.

Aspect 11C. An article for light emitting devices consisting of: at least one quantum dot formed from a process comprising disposing a group III-V semiconductor with a group II-VI semiconductor to form an alloyed core, wherein the alloyed core includes a group V-VI alloyed semiconductor emitting a bandwidth of less than 50 nanometers.

Aspect 12. The article of any of aspects 11A-11C, wherein the bandwidth is less than 40 nanometers.

Aspect 13. The article of aspect 11A-11C, wherein the step of disposing includes forming a colloidal solution of the group III-V semiconductor in a source of group II-VI semiconductor.

Aspect 14. The article of aspect 14, wherein the source of group II-VI semiconductor is a selenium source.

Aspect 15. The article of aspect 15, wherein the source includes alkyl selenol.

Aspect 16. The article of aspect 11A-11C, further comprising a first layer and a second layer, wherein the quantum dot is placed in solution and disposed between the first layer and the second layer.

Aspect 17. The article of aspect 16, wherein at least one of the first layer and the second layer includes a barrier film, wherein the barrier film comprises a polysilazane-based polymer, a polysiloxane-based polymer, or a combination thereof.

Aspect 18. The article of aspects 16-17 further comprising a functional layer located outward of at least one of the first layer and the second layer.

Aspect 19. The article of aspect 18, wherein the functional layer is a diffuser.

Aspect 20. The article of any one aspects 17-19, wherein at least one of the layers is cured using one or more of a radiation curing process and a thermal curing process.

Aspect 21. The film of aspect 16, wherein the quantum dot solution is disposed on at least one of the first layer and the second layer by a solution coating process, the solution coating process includes at least one of roll coating, gravure coating, knife coating, dip coating, curtain flow coating, spray coating, bar coating, die coating, spin coating or inkjet coating, or dispenser coating.

Aspect 22. A light emitting device comprising the film of any one of aspects 11-21.

Aspect 23A. A method comprising: providing a group III-V semiconductor material with a group II-VI semiconductor material to form an alloyed core comprising a group V-VI compound having a bandwidth of less than 50 nanometers.

Aspect 23B. A method consisting essentially of: providing a group III-V semiconductor material with a group II-VI semiconductor material to form an alloyed core comprising a group II-III-V-VI compound having a bandwidth of less than 50 nanometers.

Aspect 23C. A method consisting of: providing a group III-V semiconductor material with a group II-VI semiconductor material to form an alloyed core comprising a group V-VI compound having a bandwidth of less than 50 nanometers.

Aspect 24. The method of any of aspects 23A-23C, wherein the step of providing includes forming the alloyed core through a colloidal process.

Aspect 25. The method of any of aspects 23A-24, wherein the step of providing includes providing the group III-V semiconductor material in a source material containing the group II-VI semiconductor material.

Aspect 26. The method of aspect 25, wherein the source material contains selenium.

Aspect 27. The method of aspect 25, wherein the source material includes alkyl selenol.

### Examples

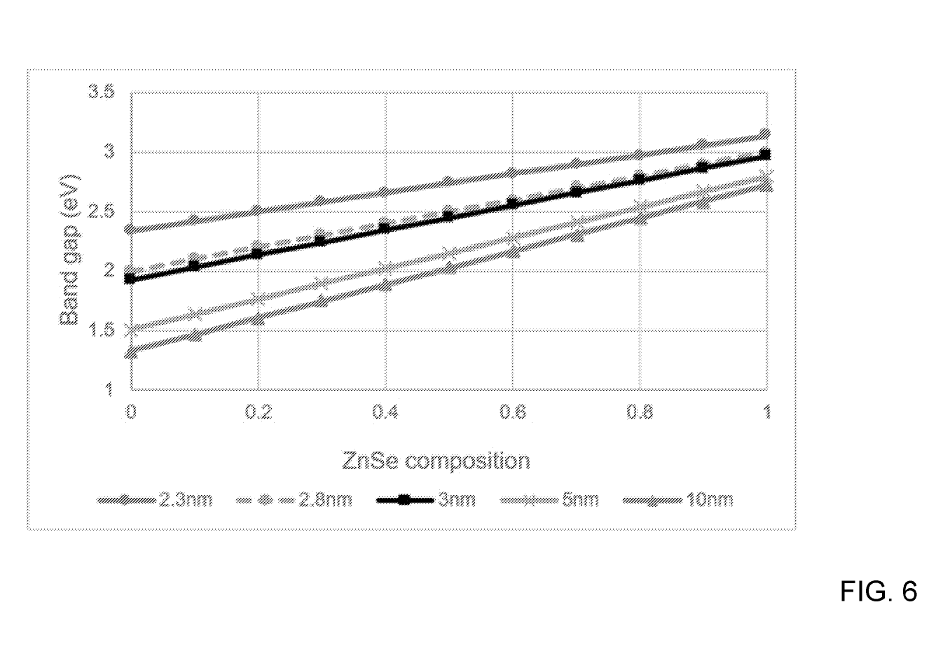

The following simulated example is put forth so as to provide those of ordinary skill in the art with a complete disclosure and description of how the films, articles and/or methods claimed herein are made and evaluated, and are intended to be purely exemplary and are not intended to limit the disclosure. According to one example, an alloyed core was prepared by mixing InP quantum dot material with a composition of ZnSe. Simulated results for this composition provided expected band gap (electronvolt, eV) variations based on the ZnSe composition are depicted in FIG. 6.

The band gap for wavelengths of 2.3 nm; 2.8 nm; 3 nm; 5 nm and 10 nm narrows relative to each other with increasing ZnSe composition. Each wavelength showed a linear increase in the band gap (eV) with increasing ZnSe composition.

Green red peak wavelengths based on a simulation of an alloyed composition with ratios of In to Zn of 10/0; 8/2; and 5/5 are shown in Table 1.

TABLE 1
Peak wavelengths based on a simulation of an
allowed composition at specific In:Zn ratios.

| Color | green | green | green | red | red | red |
|---|---|---|---|---|---|---|
| Peak wave- | 530 | 530 | 530 | 620 | 620 | 620 |
| length (nm) | | | | | | |
| Core size (nm) | 2.35 | 2.58 | 3.43 | 2.85 | 3.4 | 17 |
| In/Zn ratio | 10/0 | 8/2 | 5/5 | 10/0 | 8/2 | 5/5 |

The peak wavelength of green (530 nm) and red (620 nm) remained consistent despite the variance in the ratios of In/Zn. Moreover, variations in core size did not impact the peak wavelength. For example, for a ratio of 10/0 In/Zn, a core size of 2.35 nm is expected for the green nanoparticle with a 2.85 nm core size for a red nanoparticle. The 5/5 In/Zn ration exhibited the greatest disparity in core size with a 3.43 nm green core size and a 17 nm red core size. The difference of over 14 nm producing consistent peak emission wavelengths in comparison to small differences in core size exhibited by the 10/0 and 8/2 ratios. Such results demonstrate that it is not necessary to have uniform quantum dot size to achieve suitable light emission. Quantum dots alloyed with larger bandgap material can produce narrow FWHM luminescent spectra even though the dot size is not uniform. Moreover, angstrom differences in size are well tolerated in producing consistent luminescence at particular wavelengths.

### Definitions

It is to be understood that the terminology used herein is for the purpose of describing particular aspects only and is not intended to be limiting. As used in the specification and in the claims, the term “comprising” can include the embodiments “consisting of” and “consisting essentially of” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range. The statement “about X to Y” has the same meaning as “about X to about Y,” unless indicated otherwise. Likewise, the statement “about X, Y, or about Z” has the same meaning as “about X, about Y, or about Z,” unless indicated otherwise. The term “about” as used herein can allow for a degree of variability in a value or range, for example, within 10%, within 5%, or within 1% of a stated value or of a stated limit of a range, and includes the exact stated value or range. The term “substantially” as used herein refers to a majority of, or mostly, as in at least about 50%, 60%, 70%, 80%, 90%, 95%, 96%, 97%, 98%, 99%, 99.5%, 99.9%, 99.99%, or at least about 99.999% or more, or 100%.

In this document, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, it is to be understood that the phraseology or terminology employed herein, and not otherwise defined, is for the purpose of description only and not of limitation. Any use of section headings is intended to aid reading of the document and is not to be interpreted as limiting; information that is relevant to a section heading may occur within or outside of that particular section.

In the methods described herein, the acts can be carried out in any order without departing from the principles of the invention, except when a temporal or operational sequence is explicitly recited. Furthermore, specified acts can be carried out concurrently unless explicit claim language recites that they be carried out separately. For example, a claimed act of doing X and a claimed act of doing Y can be conducted simultaneously within a single operation, and the resulting process will fall within the literal scope of the claimed process.

The term “organic group” as used herein refers to any carbon-containing functional group. For example, an oxygen-containing group such as an alkoxy group, aryloxy group, aralkyloxy group, oxo(carbonyl) group, a carboxyl group including a carboxylic acid, carboxylate, and a carboxylate ester; a sulfur-containing group such as an alkyl and aryl sulfide group; and other heteroatom-containing groups. Non-limiting examples of organic groups include OR, OOR, OC(O)N(R)₂, CN, CF₃, OCF₃, R, C(O), methylenedioxy, ethylenedioxy, N(R)₂, SR, SOR, SO₂R, SO₂N(R)₂, SO₃R, C(O)R, C(O)C(O)R, C(O)CH₂C(O)R, C(S)R, C(O)OR, OC(O)R, C(O)N(R)₂, OC(O)N(R)₂, C(S)N(R)₂, (CH₂)₀₋₂N(R)C(O)R, (CH₂)₀₋₂N(R)N(R)₂, N(R)N(R)C(O)R, N(R)N(R)C(O)OR, N(R)N(R)CON(R)₂, N(R)SO₂R, N(R)SO₂N(R)₂, N(R)C(O)OR, N(R)C(O)R, N(R)C(S)R, N(R)C(O)N(R)₂, N(R)C(S)N(R)₂, N(COR)COR, N(OR)R, C(═NH)N(R)₂, C(O)N(OR)R, C(═NOR)R, and substituted or unsubstituted (C₁-C₁₀₀)hydrocarbyl, wherein R can be hydrogen (in examples that include other carbon atoms) or a carbon-based moiety, and wherein the carbon-based moiety can be substituted or unsubstituted.

The term “substituted” as used herein in conjunction with a molecule or an organic group as defined herein refers to the state in which one or more hydrogen atoms contained therein are replaced by one or more non-hydrogen atoms. The term “functional group” or “substituent” as used herein refers to a group that can be or is substituted onto a molecule or onto an organic group. Examples of substituents or functional groups include, but are not limited to, a halogen (e.g., fluorine F, chlorine C₁, bromine Br, and iodine I); an oxygen atom in groups such as hydroxy groups, alkoxy groups, aryloxy groups, aralkyloxy groups, oxo(carbonyl) groups, carboxyl groups including carboxylic acids, carboxylates, and carboxylate esters; a sulfur atom in groups such as thiol groups, alkyl and aryl sulfide groups, sulfoxide groups, sulfone groups, sulfonyl groups, and sulfonamide groups; a nitrogen atom in groups such as amines, hydroxyamines, nitriles, nitro groups, N-oxides, hydrazides, azides, and enamines; and other heteroatoms in various other groups. Non-limiting examples of substituents that can be bonded to a substituted carbon (or other) atom include F, Cl, Br, I, OR, OC(O)N(R)₂, CN, NO, NO₂, ONO₂, azido, CF₃, OCF₃, R, O (oxo), S (thiono), C(O), S(O), methylenedioxy, ethylenedioxy, N(R)₂, SR, SOR, SO₂R, SO₂N(R)₂, SO₃R, C(O)R, C(O)C(O)R, C(O)CH₂C(O)R, C(S)R, C(O)OR, OC(O)R, C(O)N(R)₂, OC(O)N(R)₂, C(S)N(R)₂, (CH₂)₀₋₂N(R)C(O)R, (CH₂)₀₋₂N(R)N(R)₂, N(R)N(R)C(O)R, N(R)N(R)C(O)OR, N(R)N(R)CON(R)₂, N(R)SO₂R, N(R)SO₂N(R)₂, N(R)C(O)OR, N(R)C(O)R, N(R)C(S)R, N(R)C(O)N(R)₂, N(R)C(S)N(R)₂, N(COR)COR, N(OR)R, C(═NH)N(R)₂, C(O)N(OR)R, and C(═NOR)R, wherein R can be hydrogen or a carbon-based moiety; for example, R can be hydrogen, (C₁-C₁₀₀)hydrocarbyl, alkyl, acyl, cycloalkyl, aryl, aralkyl, heterocyclyl, heteroaryl, or heteroarylalkyl; or wherein two R groups bonded to a nitrogen atom or to adjacent nitrogen atoms can together with the nitrogen atom or atoms form a heterocyclyl.

The term “alkyl” as used herein refers to straight chain and branched alkyl groups and cycloalkyl groups. Examples of straight chain alkyl groups include those with from 1 to 8 carbon atoms such as methyl, ethyl, n-propyl, n-butyl, n-pentyl, n-hexyl, n-heptyl, and n-octyl groups. Examples of branched alkyl groups include, but are not limited to, isopropyl, iso-butyl, sec-butyl, t-butyl, neopentyl, isopentyl, and 2,2-dimethylpropyl groups.

The term “alkenyl” as used herein refers to straight and branched chain and cyclic alkyl groups as defined herein, except that at least one double bond exists between two carbon atoms.

The term “acyl” as used herein refers to a group containing a carbonyl moiety wherein the group is bonded via the carbonyl carbon atom.

The term “cycloalkyl” as used herein refers to cyclic alkyl groups such as, but not limited to, cyclopropyl, cyclobutyl, cyclopentyl, cyclohexyl, cycloheptyl, and cyclooctyl groups. In some embodiments, the cycloalkyl group can have 3 to about 8-12 ring members, whereas in other embodiments the number of ring carbon atoms range from 3 to 4, 5, 6, or 7

The term “aryl” as used herein refers to cyclic aromatic hydrocarbon groups that do not contain heteroatoms in the ring. Thus aryl groups include, but are not limited to, phenyl, azulenyl, heptalenyl, biphenyl, indacenyl, fluorenyl, phenanthrenyl, triphenylenyl, pyrenyl, naphthacenyl, chrysenyl, biphenylenyl, anthracenyl, and naphthyl groups.

The term “heterocyclyl” as used herein refers to aromatic and non-aromatic ring compounds containing three or more ring members, of which one or more is a heteroatom such as, but not limited to, N, O, and S.

The term “alkoxy” as used herein refers to an oxygen atom connected to an alkyl group, including a cycloalkyl group, as are defined herein.

The terms “halo,” “halogen,” or “halide” group, as used herein, by themselves or as part of another substituent, mean, unless otherwise stated, a fluorine, chlorine, bromine, or iodine atom.

The term “haloalkyl” group, as used herein, includes mono-halo alkyl groups, poly-halo alkyl groups wherein all halo atoms can be the same or different, and per-halo alkyl groups, wherein all hydrogen atoms are replaced by halogen atoms, such as fluoro. Examples of haloalkyl include trifluoromethyl, 1,1-dichloroethyl, 1,2-dichloroethyl, 1,3-dibromo-3,3-difluoropropyl, perfluorobutyl, and the like.

The term “hydrocarbon” or “hydrocarbyl” as used herein refers to a molecule or functional group, respectively, that includes carbon and hydrogen atoms. The term can also refer to a molecule or functional group that normally includes both carbon and hydrogen atoms but wherein all the hydrogen atoms are substituted with other functional groups.

As used herein, the term “hydrocarbyl” refers to a functional group derived from a straight chain, branched, or cyclic hydrocarbon, and can be alkyl, alkenyl, alkynyl, aryl, cycloalkyl, acyl, or any combination thereof. Hydrocarbyl groups can be shown as (Cₐ-C_{b})hydrocarbyl, wherein a and b are integers and mean having any of a to b number of carbon atoms. For example, (C₁-C₄)hydrocarbyl means the hydrocarbyl group can be methyl (C₁), ethyl (C₂), propyl (C₃), or butyl (C₄), and (C₀-C_{b})hydrocarbyl means in certain embodiments there is no hydrocarbyl group.

The term “number-average molecular weight” (Mₙ) as used herein refers to the ordinary arithmetic mean of the molecular weight of individual molecules in a sample. It is defined as the total weight of all molecules in a sample divided by the total number of molecules in the sample. Experimentally, Mₙ is determined by analyzing a sample divided into molecular weight fractions of species i having nᵢ molecules of molecular weight Mᵢ through the formula Mₙ=ΣMᵢnᵢ/Σnᵢ. The Mₙ can be measured by a variety of well-known methods including gel permeation chromatography, spectroscopic end group analysis, and osmometry. If unspecified, molecular weights of polymers given herein are number-average molecular weights.

The term “weight-average molecular weight” as used herein refers to M_{w}, which is equal to ΣMᵢ²nᵢ/ΣMᵢnᵢ, where nᵢ is the number of molecules of molecular weight Mᵢ. In various examples, the weight-average molecular weight can be determined using light scattering, small angle neutron scattering, X-ray scattering, and sedimentation velocity.

The term “radiation” as used herein refers to energetic particles travelling through a medium or space. Examples of radiation are visible light, infrared light, microwaves, radio waves, very low frequency waves, extremely low frequency waves, thermal radiation (heat), and black-body radiation.

The term “UV light” as used herein refers to ultraviolet light, which is electromagnetic radiation with a wavelength of about 10 nm to about 400 nm.

The term “cure” as used herein refers to exposing to radiation in any form, heating, or allowing to undergo a physical or chemical reaction that results in hardening or an increase in viscosity.

The term “solvent” as used herein refers to a liquid that can dissolve a solid, liquid, or gas. Non-limiting examples of solvents are silicones, organic compounds, water, alcohols, ionic liquids, and supercritical fluids.

The term “coating” as used herein refers to a continuous or discontinuous layer of material on the coated surface, wherein the layer of material can penetrate the surface and can fill areas such as pores, wherein the layer of material can have any three-dimensional shape, including a flat or curved plane. In one example, a coating can be formed on one or more surfaces, any of which may be porous or nonporous, by immersion in a bath of coating material.

The term “surface” as used herein refers to a boundary or side of an object, wherein the boundary or side can have any perimeter shape and can have any three-dimensional shape, including flat, curved, or angular, wherein the boundary or side can be continuous or discontinuous. While the term surface generally refers to the outermost boundary of an object with no implied depth, when the term ‘pores’ is used in reference to a surface, it refers to both the surface opening and the depth to which the pores extend beneath the surface into the substrate.

As used herein, the term “polymer” refers to a molecule having at least one repeating unit and can include copolymers.

The polymers described herein can terminate in any suitable way. In some embodiments, the polymers can terminate with an end group that is independently chosen from a suitable polymerization initiator, —H, —OH, a substituted or unsubstituted (C₁-C₂₀)hydrocarbyl (e.g., (C₁-C₁₀)alkyl or (C₆-C₂₀)aryl) interrupted with 0, 1, 2, or 3 groups independently selected from —O—, substituted or unsubstituted —NH—, and —S—, a poly(substituted or unsubstituted (C₁-C₂₀)hydrocarbyloxy), and a poly(substituted or unsubstituted (C₁-C₂₀)hydrocarbylamino).

Illustrative types of polyethylene include, for example, ultra-high molecular weight polyethylene (UHMWPE, for example, a molar mass between 3.5 and 7.5 million atomic mass units), ultra-low molecular weight polyethylene (ULMWPE), high molecular weight polyethylene (HMWPE), high density polyethylene (HDPE, for example, a density of about 0.93 to 0.97 grams per cubic centimeter (g/cm³) or 970 kilograms per cubic meter (kg/m³)), high density cross-linked polyethylene (HDXLPE, for example, a density of about 0.938 to about 0.946 g/cm³), cross-linked polyethylene (PEX or XLPE, for example, a degree of cross-linking of between 65 and 89% according to ASTM F876), medium density polyethylene (MDPE, for example, a density of 0.926 to 0.940 g/cm³), low density polyethylene (LDPE, for example, about 0.910 g/cm³ to 0.940 g/cm³), linear low density polyethylene (LLDPE) and very low density polyethylene (VLDPE, for example, a density of about 0.880 to 0.915 g/cm³). While typical aspects have been set forth for the purpose of illustration, the foregoing descriptions should not be deemed to be a limitation on the scope herein. Accordingly, various modifications, adaptations, and alternatives can occur to one skilled in the art without departing from the spirit and scope herein.

It will be apparent to those skilled in the art that various modifications and variations can be made in the present disclosure without departing from the scope or spirit of the disclosure. Other embodiments of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

The patentable scope of the disclosure is defined by the claims, and can include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. An article comprising:
a first layer and a second layer; and
a quantum dot layer disposed between the first layer and the second layer,
wherein the quantum dot layer includes at least one quantum dot having an alloyed core,
wherein the alloyed core includes a group III-V semiconductor alloyed with a group II-VI cadmium free compound, and wherein the core emits a bandwidth less than 50 nanometers.

2. The article of claim 1, wherein the bandwidth is less than 40 nanometers.

3. The article of claim 1, wherein alloyed core is indium phosphide.

4. The article of claim 1, wherein the alloyed core is iron selenide.

5. The article of claim 1, wherein the first layer and the second layer each include a barrier film.

6. The article of claim 1, further comprising a functional layer provided outward of at least one of the first layer and the second layer.

7. The article of claim 6, wherein the functional layer is a diffuser.

8. The article of claim 1, wherein the quantum dot layer is disposed on the first layer using a solution coating process.

9. A light emitting device comprising the article of claim 1.

10. An article for light emitting devices comprising: at least one quantum dot formed from a process comprising disposing a group III-V semiconductor with a group II-VI semiconductor to form an alloyed core, wherein the alloyed core includes a group II-III-V-VI alloyed semiconductor emitting a bandwidth of less than 50 nanometers.

11. The article of claim 10, wherein the bandwidth is less than 40 nanometers.

12. The article of claim 10, wherein the disposing comprises forming a colloidal solution of the group III-V semiconductor in a source of the group II-VI semiconductor.

13. The article of claim 12, wherein the source of group II-VI semiconductor is a selenium source.

14. The article of claim 12, wherein the source of group II-VI semiconductor comprises alkyl selenol.

15. The article of claim 10, further comprising a first layer and a second layer, wherein the quantum dot is in solution to form a quantum dot solution, and wherein the quantum dot solution is disposed between the first layer and the second layer.

16. The article of claim 10, wherein at least one of the first layer and the second layer comprises a barrier film, wherein the barrier film comprises a polysilazane-based polymer, a polysiloxane-based polymer, or a combination thereof.

17. The article of claim 15 further comprising a functional layer located outward of at least one of the first layer and the second layer.

18. The article of claim 15, wherein at least one of the first layer and the second layer is cured using one or more of a radiation curing process and a thermal curing process.

19. The article of claim 15, wherein the quantum dot solution is disposed on at least one of the first layer and the second layer by a solution coating process, the solution coating process includes at least one of roll coating, gravure coating, knife coating, dip coating, curtain flow coating, spray coating, bar coating, die coating, spin coating or inkjet coating, or dispenser coating.

20. A light emitting device comprising the article of claim 10.
